(19) United States
(12) Patent Application Publication
(10) Pub. No.: US 2008/0090387 A1
(43) Pub. Date: Apr. 17, 2008

(54) Method of making semiconductor element

(75) Inventor: Yukio Shakuda, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/901,281

(22) Filed: Sep. 14, 2007

(30) Foreign Application Priority Data
Sep. 14, 2006 (JP) 2006-249388

(51) Int. Cl. H01L 21/20

(52) U.S. Cl. 438/479; 257/E21.09

(57) ABSTRACT

A method of making a semiconductor element is provided. The method includes a step of forming a GaN layer doped with a p-type impurity on a substrate and a step of subjecting the GaN layer to activation process to form a p-type semiconductor layer. The activation process is performed with the GaN layer immersed in molten Ga. Preferably, the molten Ga contains a p-type impurity.

### BACKGROUND OF THE INVENTION

1. Field of the Invention

The present invention relates to a method of making a semiconductor element such as a light emitting diode.

2. Description of the Related Art

In a conventional method of making a semiconductor element such as a light emitting diode, a p-type semiconductor layer made of GaN may be formed on a substrate made of sapphire (see JP-A-H05-183189, for example). To form a p-type semiconductor layer, a GaN layer doped with Mg is first formed on a sapphire substrate. Then, the sapphire substrate is heated in an atmosphere of e.g. N₂ to 400 to 800° C. Consequently, Mg in the GaN layer is activated, whereby the GaN layer becomes a p-type semiconductor layer. The surface of the p-type semiconductor layer is formed with e.g. a p-type electrode for injecting holes into the semiconductor layer.

Proper activation of Mg in the GaN layer can be performed by increasing the heating temperature for the GaN layer. However, as the heating temperature becomes higher, the GaN layer is more likely to undergo the decomposition of GaN at its surface, which makes the surface layer of the resultant p-type semiconductor layer N-deficient. Such a surface condition hinders the formation of a good ohmic contact between the p-type semiconductor layer and the p-type electrode, which is not desirable.

### SUMMARY OF THE INVENTION

The present invention has been proposed under the circumstances described above. It is, therefore, an object of the present invention to provide a method of making a semiconductor element which is capable of forming a good ohmic contact between a p-type semiconductor layer and a p-type electrode, for example.

According to the present invention, a method of making a semiconductor element is provided. The method includes a step of forming a GaN layer doped with a p-type impurity on a substrate and a step of subjecting the GaN layer to activation process to form a p-type semiconductor layer. The activation process is performed with the GaN layer immersed in molten Ga.

Preferably, the molten Ga contains a p-type impurity.

Other features and advantages of the present invention will become more apparent from detailed description-given below with reference to the accompanying drawings.

### BRIEF DESCRIPTION OF THE DRAWINGS

FIG. 1 is a sectional view showing the step of forming a GaN layer in the manufacturing method according to a first embodiment of the present invention;

FIG. 2 is a sectional view showing the activation process in the manufacturing method;

FIG. 3 is a sectional view showing an example of semiconductor light emitting elements made by the manufacturing method;

FIG. 4 is a photomicrograph of a p-GaN layer obtained by the activation process;

FIG. 5 is a photomicrograph of a p-GaN layer obtained by conventional activation process;

FIG. 6 is a graph showing the relationship between the activation temperature and the resistance;

FIG. 7 is a graph showing the measurement results of the carrier concentration;

FIG. 8 is a graph showing the relationship between the depth from the surface and the Mg concentration;

FIG. 9 is a sectional view showing the step of forming a buffer layer, an n-GaN layer, an active layer and a GaN layer in the manufacturing method according to a second embodiment; and

FIG. 10 is a sectional View showing the activation process in the manufacturing method according to the second embodiment.

### DETAILED DESCRIPTION OF THE PREFERRED EMBODIMENTS

Preferred embodiments of the present invention will be described below with reference to the accompanying drawings.

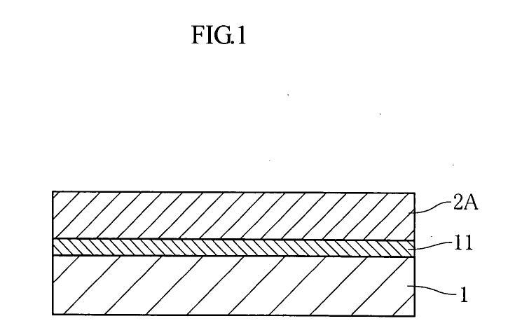

FIGS. 1-3 show a method of making a semiconductor element according to a first embodiment of the present invention. First, a substrate assembly shown in FIG. 1 is prepared. The substrate assembly includes a substrate 1, a buffer layer 11 and a GaN layer 2A. The substrate 1 may be made of any of sapphire, SiC and Si. The substrate assembly is formed as follows.

First, a substrate 1 is prepared and cleaned. Specifically, the substrate 1 is put into a film formation chamber of a metal organic chemical vapor deposition (MOCVD) apparatus, for example. Then, with the temperature in the film formation chamber (hereinafter referred to as “chamber temperature”) maintained at 1100° C., H₂ gas and N₂ gas are supplied into the film formation chamber, to clean the substrate 1. After the cleaning, a buffer layer 11 is formed on a surface (upper surface in FIG. 1) of the substrate 1. The buffer layer 11 may be made of AlN or GaN or AlGaN, for example.

Then, a GaN layer 2A is formed on the buffer layer 11. Specifically, with the chamber temperature maintained at e.g. 1010° C., NH₃ gas, H₂ gas, N₂ gas and trimethyl gallium (TMG) gas are supplied into the chamber. At the same time, Cp₂Mg gas containing Mg, which is a p-type impurity, is supplied into the film formation chamber. In this way, a GaN layer 2A doped with Mg is formed.

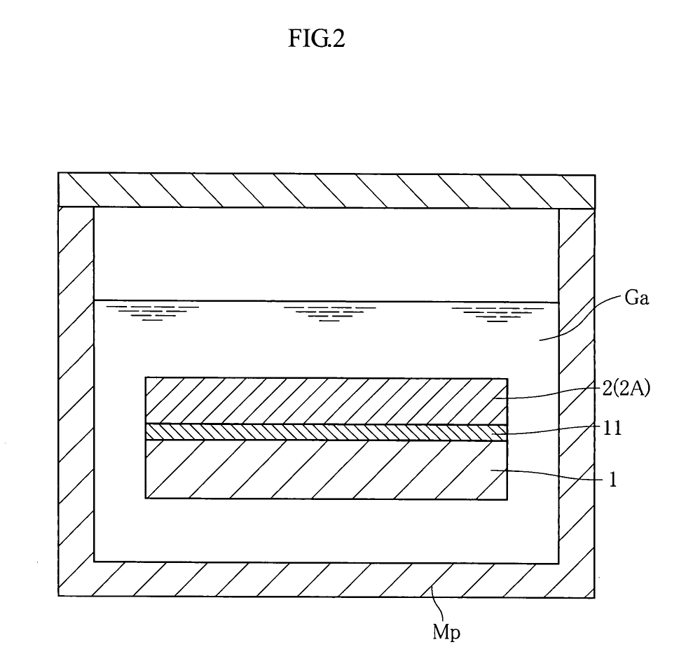

Then, as shown in FIG. 2, a melting pot Mp made of e.g. Al₂O₃ is prepared, and an appropriate amount of molten Ga is put into the pot. Mg, as a p-type impurity, is added to the molten Ga. In this process, Ga is heated to about 500 to 600° C. so that Mg is melted uniformly in the molten Ga. Then, an activation process of the GaN layer 2A is performed. Specifically, the substrate assembly (i.e., the substrate 1 formed with the buffer layer 11 and the GaN layer 2A) is immersed in the Ga in the melting pot Mp, and the melting pot Mp is closed with a lid. Then, with the pressure in the melting pot Mp maintained at about 600 to 760 Torr, Ga is heated to about 800 to 960° C. By maintaining this state for 60 minutes, Mg contained in the GaN layer 2A is activated, whereby the GaN layer 2A becomes a p-GaN layer 2.

After the activation process, the substrate 1 is taken out of the melting pot Mp and then cleaned using several kinds of cleaning liquid. Specifically, the substrate 1 and the p-GaN layer 2 are cleaned by alternately using H₂O, diluted hydrochloric acid (HCl:H₂O=1:10 (weight ratio)) and hydrochloric acid. In this process, the temperature of each cleaning liquid may be kept at 40 to 50° C.

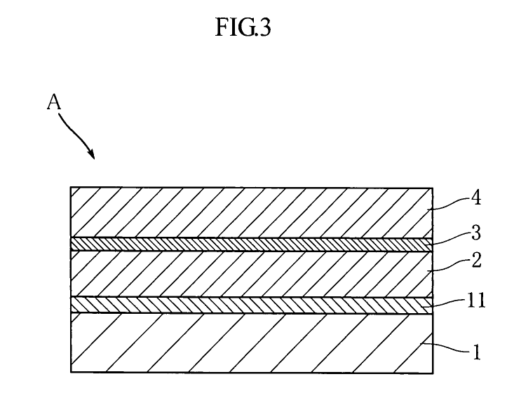

Then, as shown in FIG. 3, an active layer 3 and an n-GaN layer 4 are laminated on the p-GaN layer 2. The active layer 3, having a multiple quantum well (MQW) structure containing InGaN, emits light upon recombination of electrons and holes. The active layer 3 is provided by alternate lamination of a plurality of InGaN layers and a plurality of GaN layers. The InGaN layers are well layers of the active layer 3, whereas the GaN layers are barrier layers of the active layer 3. The n-Gan layer 4 is made of an n-type semiconductor which is provided by GaN doped with Si.

To form the active layer 3, NH₃ gas, H₂ gas, N₂ gas, triethyl gallium (TEG) gas, TMG gas and trimethyl indium (TMIn) gas are supplied into the film formation chamber whose temperature is kept at 700 to 800° C. By this process, InGaN layers as well layers and GaN layers as barrier layers are alternately formed. The number of each kind of the layers is three to seven, for example. Then, after the chamber temperature is raised to and maintained at 1060° C., NH₃ gas, H₂ gas, N₂ gas and TMG gas are supplied into the film formation chamber. At the same time, SiH₄ gas is supplied to dope Si (n-type dopant). As a result, the n-GaN layer 4 is formed. Then, a p-side electrode is formed on the p-GaN layer 2, whereas an n-side electrode 2 is formed on the n-GaN layer 4. Thus, a semiconductor light emitting element A is obtained.

The technical advantages of the method of making a semiconductor element according to the above-described embodiment are as follows. As noted above, the activation process of the GaN layer 2A is performed at a high temperature in a range of 800 to 960° C. This condition makes N leave the surface of the GaN layer 2A, thereby reducing the N concentration. (In contrast, the Ga concentration at the surface becomes unduly high.) However, in the above-described manufacturing method, the activation process of the GaN layer 2A is performed in the molten Ga. In this manner, the N-lacking surface of the GaN layer 2A is removed by melting into the molten Ga, whereby the surface of the p-GaN layer 2 obtained by the activation process becomes clean (i.e., having the desired concentration of Ga and N) Thus, it is possible to make a good ohmic contact between the p-GaN layer 2 and the p-side electrode.

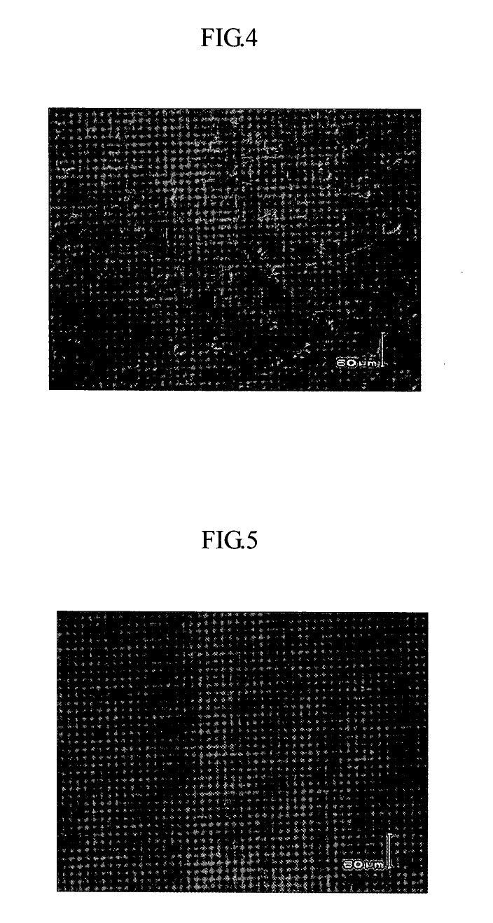

FIG. 4 is a photomicrograph of the p-GaN layer 2 obtained by the activation process in molten Ga, whereas FIG. 5 is a photomicrograph of a comparative example (i.e., a p-GaN layer resulting from the activation process in N₂ atmosphere) As shown in FIG. 4, the surface of the p-GaN layer 2 has many irregularities that are finer than those of the comparative example shown in FIG. 5. This is because the surface portion of the GaN layer, in which N lacks due to the activation, has melted into the molten Ga. Such a surface of the p-GaN layer 2 is in a proper state with no N-void portion, which is suitable for forming a good ohmic contact with the p-side electrode.

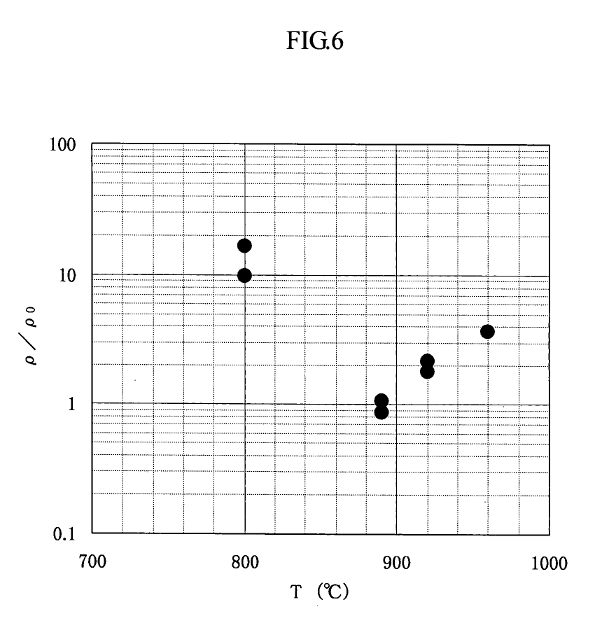

Further, since the activation process is performed in the temperature range of 800 to 960° C. in the above-described manufacturing method, Mg in the GaN layer 2A is properly activated. FIG. 6 is a graph plotting the ratio ρ/ρ₀ of two resistances with respect to the activation temperature T. Herein, ρ is the resistance of the p-GaN layer 2, whereas ρ₀ is the resistance of the above-described comparative example (i.e., p-GaN layer resulting from the activation in N₂ atmosphere). As understood from the figure, ρ/ρ₀ is about 1.0 when the activation temperature T is about 880° C. This indicates that the resistance of the p-GaN layer 2 is substantially equal to that of the comparative example, meaning that the p-GaN layer 2 does not have unduly high resistance.

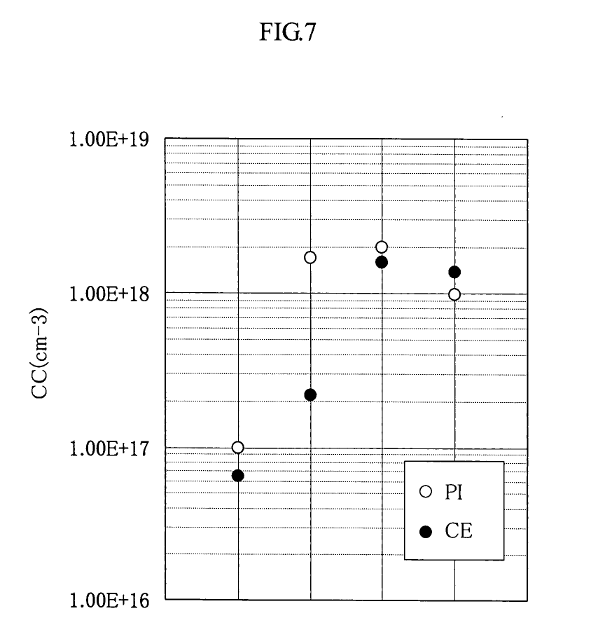

FIG. 7 shows the results of measurement of carrier concentration (CC) with respect to samples of the p-GaN layer 2 (PI) and samples of the comparative example (CE). As understood from the figure, the carrier concentration in the p-GaN layer 2 is substantially equal to or higher than that in the comparative example.

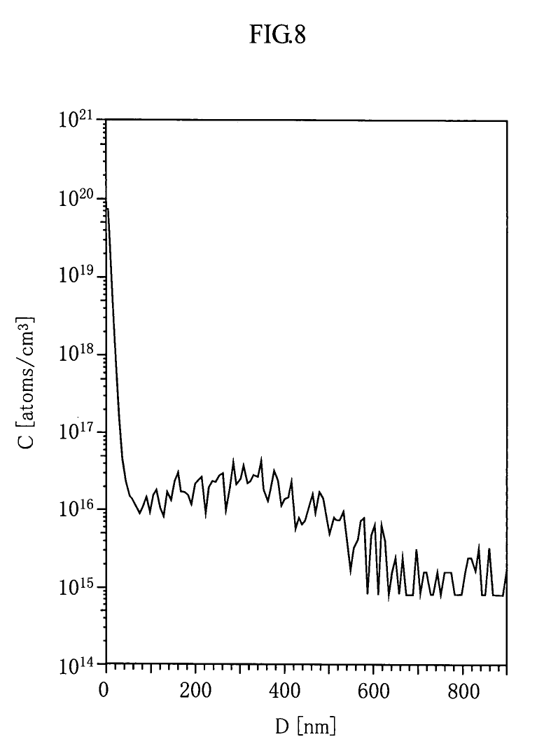

In the graph of FIG. 8, the ordinate indicates the Mg concentration C in the p-GaN layer 2, whereas the abscissa indicates the depth D from the surface of the p-GaN layer 2. As understood from the figure, the Mg concentration is considerably higher at a depth D of not more than about 80 nm than at deeper portions. This is because the Mg mixed into the molten Ga is diffused into the GaN layer 2A in the activation process. Thus, the surface of the obtained p-GaN layer 2 is suitable for forming a good ohmic contact with the p-side electrode.

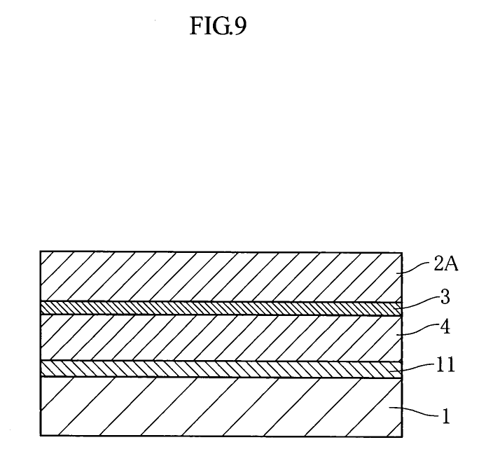

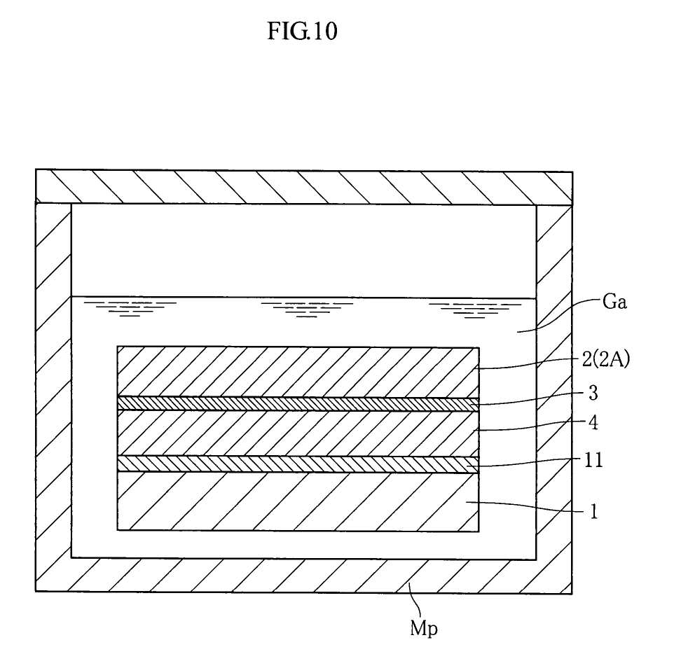

FIGS. 9 and 10 show a manufacturing method according to a second embodiment of the present invention. In these figures, the elements which are identical or similar to those of the first embodiment are designated by the same reference signs as those used for the first embodiment.

In the second embodiment, as shown in FIG. 9, a buffer layer 11, an n-GaN layer 4, an active layer 3 and a GaN layer 2A are successively laminated on a substrate 1. The method for forming the buffer layer 11, the n-GaN layer 4, the active layer 3 and the GaN layer 2A are the same as that in the first embodiment.

As shown in FIG. 10, the substrate formed with the buffer layer 11, the n-GaN layer 4, the active layer 3 and the GaN layer 2A is immersed in molten Ga in a melting pot Mp. Similarly to the first embodiment, Mg as a p-type impurity is mixed in the molten Ga in advance. After the melting pot Mp is closed with a lid, the pressure in the melting pot is set to about 600 to 760 Torr. Then, the molten Ga is heated to about 800 to 960° C., and preferably, about 880° C. This state is maintained for 60 minutes. By this activation process, Mg contained in the GaN layer 2A is activated, whereby the GaN layer 2A is turned into a p-GaN layer 2.

According to the second embodiment, a semiconductor element formed with an n-GaN layer 4 on the substrate 1 side is provided. In the activation process of this embodiment, not only the GaN layer 2A but also the n-GaN layer 4 and the active layer 3 are immersed in molten Ga. However, the thickness of the GaN layer 2A, n-GaN layer 4 and active layer 3 is very small. Thus, only the surface portion of the GaN layer 2A, which is exposed, melts into the molten Ga, whereas the n-GaN layer 4 and the active layer 3 do not melt into the molten Ga. Further, it is only the GaN layer 2A into which the Mg contained in the molten Ga diffuses. It is also advantageous that the activation temperature of about 880° C. does not damage the crystal structure or composition of the active layer 3.

The method for manufacturing a semiconductor element according to the present invention is not limited to the foregoing embodiments. For instance, the p-type impurity is not limited to Mg, and another substance (e.g. Zn) may be used as long as it can properly make a p-type semiconductor layer from the GaN layer. The manufacturing method according to the present invention is not only applicable to the manufacture of a semiconductor light emitting element but also applicable to the manufacture of various semiconductor elements utilizing a p-type semiconductor layer.

1. A method of making a semiconductor element, the method comprising the steps of:
forming a GaN layer doped with a p-type impurity on a substrate; and
subjecting the GaN layer to activation process to form a p-type semiconductor layer;
wherein the activation process is performed with the GaN layer immersed in molten Ga.

2. The method according to claim 1, wherein the molten Ga contains a p-type impurity.
